(19) United States
(12) Patent Application Publication
(10) Pub. No.: US 2026/0068632 A1
(43) Pub. Date: Mar. 5, 2026

(54) BACKSIDE POWER DELIVERY ATTACHMENT

(71) Applicant: ADEIA SEMICONDUCTOR BONDING TECHNOLOGIES INC., San Jose, CA (US)

(72) Inventors: Belgacem HABA, Saratoga, CA (US); Rajesh KATKAR, Milpitas, CA (US)

(21) Appl. No.: 18/819,029

(22) Filed: Aug. 29, 2024

(51) Int. Cl. H01L 23/528; H01L 23/367

(52) U.S. Cl. CPC H01L 23/5286

(57) ABSTRACT

A power delivery substrate may include a doped semiconductor including ground blocks, power blocks parallel to and coplanar with the ground blocks, and an insulator between the ground and power blocks. A first insulator layer can be disposed over the doped semiconductor and include first trenches and second trenches. The first and second trenches can be crossing with the ground and power blocks. First conductive traces may be included in the first trenches and in electrical contact with the ground blocks. Second conductive traces may be included in the second trenches and in electrical contact with the power blocks. A second insulator layer can be disposed over the first and the second conductive traces, and bonding pads can be embedded in the second insulator layer. The bonding pads can be electrically connected to the first and the second conductive traces.

### BACKGROUND

### Field

The field relates to semiconductor devices, and in particular, to the delivery of power and ground to semiconductor devices.

### Description of the Related Art

As features in semiconductor devices continue to shrink, power delivery issues are of increasing concern. Electrical isolation issues, limitations on feature sizes due to the high density of circuit elements and interconnects, losses due to traversing large numbers of metal layers, structural stresses owing in part to coefficient of thermal expansion (CTE) mismatches, impediments to thermal dissipation, and so forth can make it difficult to efficiently provide power to semiconductor devices. Accordingly, there is a need for improved power and ground delivery in semiconductor device assemblies.

### BRIEF DESCRIPTION OF THE DRAWINGS

Features, aspects, and advantages of the disclosure are described with reference to drawings of certain embodiments, which are intended to illustrate, but not to limit, the present disclosure. It is to be understood that the accompanying drawings, which are incorporated in and constitute a part of this specification, are for the purpose of illustrating concepts disclosed herein and may not be to scale.

FIGS. 1A-1B are schematic cross sections illustrating direct bonding of microelectronic elements, according to one embodiment.

FIG. 2A is a schematic top plan view of a power delivery substrate, according to one embodiment.

FIG. 2B is a schematic top plan view of a power delivery substrate with a cooling structure, according to one embodiment.

FIG. 2C is a schematic side cross-sectional view of a power delivery substrate, according to one embodiment.

FIGS. 3A-3D are schematic cross-sectional plan views showing different layers within a power delivery substrate, according to one embodiment.

FIGS. 4A and 4C are schematic side cross-sectional views taken along lines 4A-4A and 4C-4C of FIG. 3D, and FIGS. 4B and 4D are corresponding magnified views, along different conductive traces, according to one embodiment.

FIGS. 5A-5E are a series of schematic side cross sections illustrating a process of forming a power delivery substrate, according to one embodiment.

FIGS. 6A-6C are a series of schematic side cross sections illustrating a process of forming a power delivery substrate, according to another embodiment.

FIGS. 7A-7B are schematic cross-sectional views of a power delivery substrate and a semiconductor chip, illustrating hybrid bonding of the power delivery substrate to the semiconductor chip, and illustrating direct bonding of a cooling structure to the power delivery substrate, according to one embodiment.

Like reference numbers are used to describe like features throughout the description and drawings.

### DETAILED DESCRIPTION

Although several embodiments, examples, and illustrations are disclosed below, it will be understood by those of ordinary skill in the art that the inventions described herein extend beyond the specifically disclosed embodiments, examples, and illustrations and include other uses of the inventions and obvious modifications and equivalents thereof. Embodiments of the inventions are described with reference to the accompanying figures, wherein like numerals refer to like elements throughout. The terminology used in the description presented herein is not intended to be interpreted in any limited or restrictive manner simply because it is being used in conjunction with a detailed description of some specific embodiments of the inventions. In addition, embodiments of the inventions can comprise several novel features and no single feature is solely responsible for its desirable attributes or is essential to practicing the inventions herein described.

Conventionally, both signal transmission and power delivery occur on the frontside of semiconductor devices. However, semiconductor device features have been decreasing in size (e.g., sizes of active devices like transistors) and their density is steadily increasing. Consequently, including signal and power/ground lines on the frontside of the semiconductor devices is leading to design, process and performance bottlenecks due to higher impedances and power losses as the cross-sectional areas of vias and other circuitry are reduced, and the lengths of power lines are increased. Implementation of a backside power delivery element in semiconductor packages, as described herein, can help address some of these issues. Further, decoupling the delivery of signals from the delivery of power can free up space on the frontside of a semiconductor chip for signal lines, effectively reducing the size of device cells and the overall chip.

Delivering power to the backside of an integrated circuit faces several challenges. The delivery mechanism should be able to electrically couple to finely spaced contacts on the backside of a semiconductor chip (or chip). Backside power delivery should be dispersed across the backside of the chip. Simultaneously, backside power delivery should not hinder the dissipation of heat generated from the chip. Further, backside power delivery should mitigate structural stresses, such as from thermal expansion mismatches within the semiconductor package, which can be particularly problematic for packages incorporating thin semiconductor dies, stacked dies, assemblies implementing hybrid bonding, assemblies using very fine pitch surface mount technology (SMT), etc., as mismatched coefficients of thermal expansion (CTEs) within the package could result in structural damage during operation of the semiconductor device. Thus, techniques and structures for backside power delivery that can balance thermal dissipation requirements with the power and ground delivery requirements are needed.

To address the CTE mismatch issue, power delivery elements as described herein can be provided with a low CTE. For example, the power delivery element can include a high percentage of heavily doped semiconductor material (e.g., heavily doped silicon), resulting in an electrically conductive material that can carry large currents. Insulating material used in insulating layers within the backside power delivery element may be thin compared to the semiconductor conductors. Further, metal features to be utilized within the power delivery element, may be thin relative to the semiconductor conductors, and may also be selected to include relatively low CTE metals (e.g., tungsten, nickel, cobalt, etc.). In some embodiments, a power delivery element can be implemented for attachment to a backside of a semiconductor chip. This power delivery element (or power delivery substrate) can include a doped semiconductor layer and metallization layers. The doped semiconductor layer may include insulators to subdivide the doped semiconductor substrate into a plurality of blocks, such that individual blocks of the plurality of blocks are electrically isolated from one another. The blocks may be power blocks and/or ground blocks depending on whether an individual block is electrically connected to a power or a ground source. The blocks may be electrically coupled to a plurality of power sources having different power values. In some cases, the blocks may also be electrically coupled to a plurality of ground sources, where having multiple grounds can mitigate noise issues in a device.

Once formed, the power delivery substrate comprising a relatively thick electrically conductive doped semiconductor layer and comparatively thinner metallization layers can be directly bonded (e.g., hybrid bonded) to a backside of a semiconductor chip. The semiconductor chip can have a frontside and backside, such that the active devices (e.g., transistors) of the semiconductor chip are located nearer to the frontside than the backside of the semiconductor chip.

### Examples of Direct Bonding Methods and Directly Bonded Structures

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564 , filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

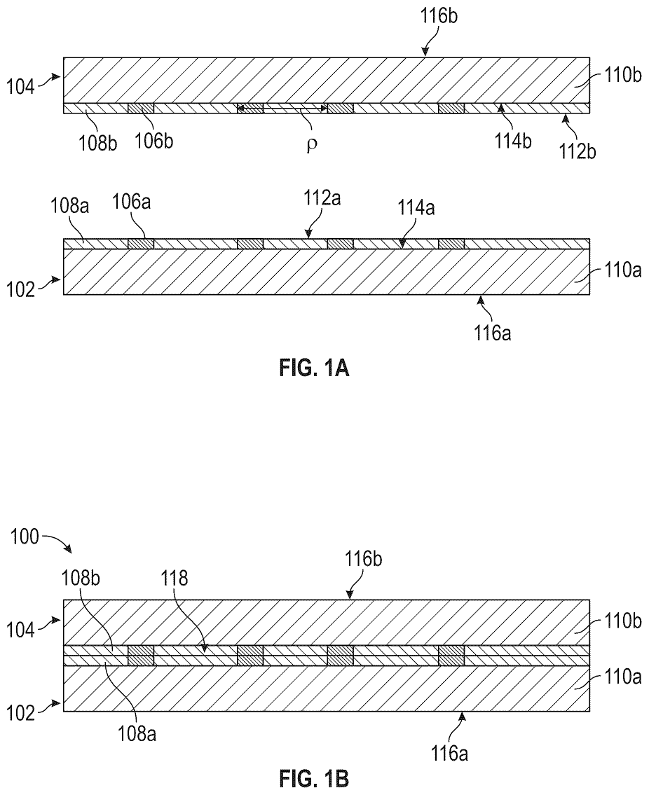

FIGS. 1A and 1B schematically illustrate cross-sectional side views of first and second elements 102, 104 prior to and after, respectively, a process for forming a directly bonded structure, and more particularly a hybrid bonded structure, according to some embodiments. In FIG. 1B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, the base substrate portions 110a, 110b may not include active circuitry, but may instead comprise dummy substrates, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO3) or lithium niobate (LiNbO3), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises a packaging material, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding layers 108a, 108b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding field regions, such that a total gap between opposing contacts after dielectric bonding and prior to anneal is less than 15 nm, or less than 10 nm. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials'melting temperature, such that bonds can form with lower anneal temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 1A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

### Examples of Power Delivery Substrates for Semiconductor Chips

Various embodiments disclosed herein relate to power delivery substrates (e.g., power and ground distribution structures) for semiconductor chips. In particular, power delivery substrates for backside power delivery in semiconductor packages or microelectronic devices are described.

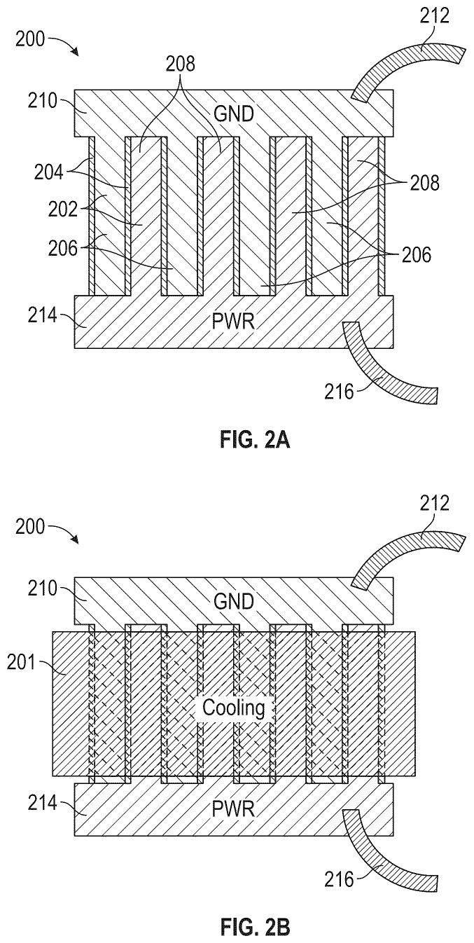

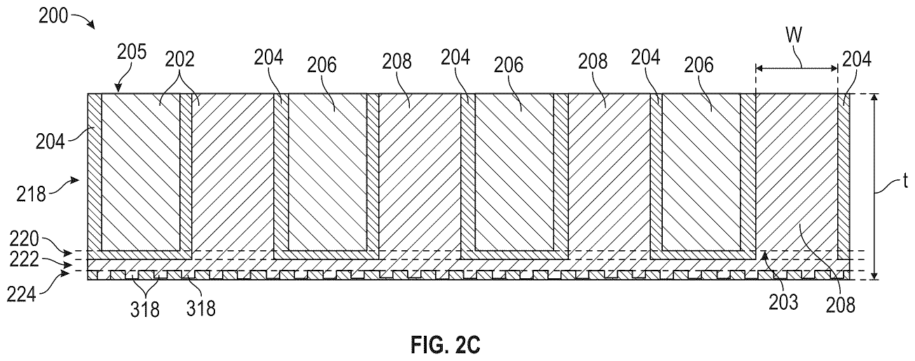

FIG. 2A illustrates a top view of a power delivery substrate 200 that can be attached to a chip for power/ground delivery. In some embodiments, the power delivery substrate 200 can be devoid of active devices. The power delivery substrate 200 can be formed from a semiconductor material that is doped for conductivity. For example, the power delivery substrate 200 can be formed from a doped silicon material (e.g., a doped silicon crystal or a doped polycrystalline silicon). In some embodiments, the doped silicon crystal can have a doping concentration between approximately 10¹⁸ atoms/cm³ and approximately 10²² atoms/cm³. In some cases, the doped silicon crystal can have a doping concentration between approximately 10¹⁸ atoms/cm³ and approximately 10¹⁹ atoms/cm³. The doped silicon crystal can be doped with at least one of arsenic, boron, phosphorous, gallium, and etc. The dopant can be selected to allow the doped semiconductor material to donate or to accept electrons. The doped semiconductor can be a doped n-type or a doped p-type semiconductor material. The doped semiconductor can have only a single layer of semiconductor blocks or lines, without additional vertical layers of semiconductor blocks or lines, and without insulation vertically separating sections of the single layer. The doped semiconductor of the power delivery substrate 200 can have a thermal conductivity at room temperature in a range between approximately 50 Wm⁻¹K⁻¹ and 200 Wm⁻¹K⁻¹, or in a range between approximately 30 Wm⁻¹K⁻¹ and 150 Wm⁻¹K⁻¹. The relatively high thermal conductivities can enable a thermal pathway to exist through the power delivery substrate 200 to extract heat from the active integrated circuit to be bonded to it. The doped semiconductor can be selected to have a CTE in a range between approximately 2×10⁻⁶ K⁻¹ and 4×10⁻⁶ K⁻¹, or between approximately 2.5×10⁻⁶ K⁻¹ and 3.5×10⁻⁶ K⁻¹. The relatively low CTE values are relatively close to that of the chip to which the power delivery substrate 200 is to be bonded and can help improve the structural integrity of the semiconductor device during operation.

The power delivery substrate 200 can be divided into blocks 202 (e.g., regions), and the blocks 202 can be electrically separated from one another through the inclusion of insulating layers 204. In some cases, the blocks 202 can extend along a majority of a length or a width of the power delivery substrate 200 (e.g., along a length of the doped semiconductor substrate, which can be a wafer during manufacture, or the illustrated substrate 200 after singulation). In some embodiments, the insulating layers 204 can include an oxide or a nitride (e.g., silicon oxide, silicon nitride, silicon oxynitride, silicon carbonitride, aluminum oxide, titanium oxide, etc.), and it can have a thickness in a range between approximately 0.1 μm and 5 μm. In some embodiments, the insulating layer can comprise two or more conformal layers. In some cases, the insulating layers 204 can include an inorganic dielectric. In some embodiments, the insulating layers 204 can include an organic dielectric (e.g. BCB). The material of the insulating layers 204 can have a CTE between approximately 0.5×10⁻⁶ K⁻¹ and 5×10⁻⁶ K⁻¹. In some embodiments, the blocks 202 can be divided into a subset of blocks to be coupled to a ground (e.g., ground blocks 206) and a subset of blocks to be coupled to a power (e.g., power blocks 208). In some cases, the ground blocks 206 and the power blocks 208 can be parallel to one another. In some cases, the ground blocks 206 and the power blocks 208 can be coplanar. In some cases, the power delivery substrate 200 includes only a single layer of doped semiconductor material, and the ground blocks 206 and the power blocks 208 are coplanar within this single layer. In some cases, the ground blocks 206 can alternate with the power blocks 208 as shown. The skilled artisan will appreciate that, until connected to ground and power, the blocks 206, 208 can be indistinguishable from one another.

As shown in FIG. 2A, a first connector rail (e.g., a ground rail 210) can be connected to ground through a ground connection element 212 (e.g., a wire) and this connection to ground facilitates the designation of the subset of blocks 202 connected to the ground rail 210 as the ground blocks 206. The first connector rail can electrically connect the ground blocks 206 to one another, such that individual blocks of the ground blocks 206 may all be connected to a same ground source (not shown). Similarly, a second connector rail (e.g., a power rail 214) can be connected to a power through a power connection element 216 (e.g., a wire), and this connection to power facilitates the designation of the subset of blocks 202 connected to the power rail 214 as the power blocks 208. The second connector rail can electrically connect the power blocks 208 to one another, such that individual blocks of the power blocks 208 may all be connected to a same power source (not shown). In some embodiments, at least the first and the second connector rails may be oriented such that they are perpendicular to the blocks 202 (e.g., perpendicular to the ground blocks 206 and the power blocks 208). As shown, the connector rails 210, 214 can also be a doped semiconductor, thus reducing metal contact for the substrate 200 and lowering the overall CTE.

Although one ground source and one power source have been illustrated, in some embodiments, the blocks 202 can include electrical connections to multiple grounds and/or multiple powers. For example, different ground blocks 206 can be electrically connected to different ground sources (e.g., by way of multiple ground rails or contacts), and/or different power blocks 208 can be electrically different power sources (e.g., by way of multiple power rails or contacts). In some examples, the blocks 202 (or a subset thereof) can be electrically connected to one ground rail and two or more power rails, where the two or more power rails are electrically connected to power sources having different voltage values. This configuration is conducive to chips that may have multiple voltage requirements. Even with the same nominal voltage, it may be advantageous in some cases to connect multiple power sources to reduce voltage drops over long distances. In some examples, a subset of the blocks 202 can be electrically connected to two or more ground rails, creating multiple ground paths, which can help with noise-related issues in a chip. In some cases, having multiple grounds paths may mitigate overheating that might otherwise occur if there was a single ground path. In some cases, electrically connecting to two or more ground rails can reduce the inductance of the ground paths. In some cases, the multiple ground paths resulting from electrically connecting to two or more ground rails can be kept separate to avoid coupling digital circuits into analog signals.

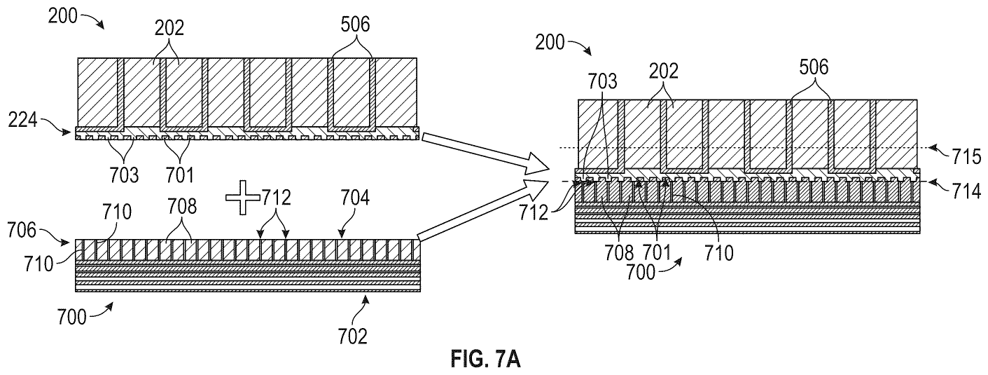

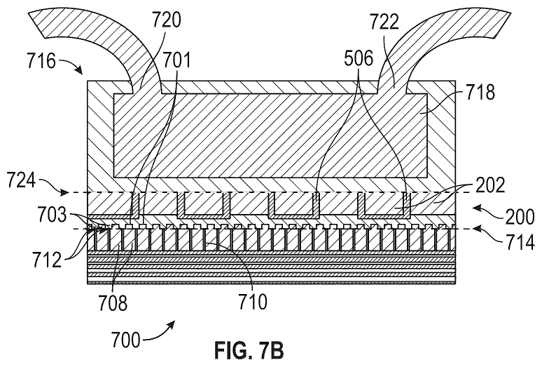

The power delivery substrate 200 can be directly bonded to a backside of a chip 700 (FIG. 7) to deliver power and/or connect ground to the chip 700. The materials selected and the configuration implemented in the power delivery substrate 200 allow for vertical thermal conduction, such that heat generated from the chip bonded to the power delivery substrate 200 can be readily dissipated through the power delivery substrate 200. For example, the blocks 202 are relatively wide and only one layer of blocks 202 is formed in the illustrated embodiment, such that thermal resistance from intervening insulators is minimized. Any horizontal insulators are significantly thinner than the blocks 202. As shown in FIG. 2B, in some embodiments, a cooling structure 201 (e.g., liquid channels, heat sink, heat pipe, etc.) can be coupled to the back of the power delivery substrate 200, or the side opposite the chip 700 (see cooling structure 716 in FIG. 7B), and facilitate heat dissipation of the structure, further enhancing the operation of the semiconductor device.

FIG. 2C illustrates a side cross-sectional view of the power delivery substrate 200. The power delivery substrate 200 is illustrated to show the blocks 202 divided into the ground blocks 206 and the power blocks 208, where individual blocks 202 are electrically separated or isolated from one another by the insulating layers 204. A block 202 can have a width w, having a value in a range between approximately 5 μm and 5 mm, such as between approximately 10 μm and 100 μm, between approximately 5 μm and 50 μm, between approximately 1 mm and 2 mm, or between approximately 1 mm and 5 mm. The power delivery substrate 200 can be multi-layered, including at least a block layer 218, a via layer 220, a conductive trace layer 222, and a bonding pad layer 224. The layers 218-224 will be described in more detail herein. The power delivery substrate 200 can have a thickness of t, having a value in a range between approximately 10 μm and 500 μm, such as between approximately 25 μm and 150 μm, or in a range between approximately 50 μm and 100 μm. The block layer 218 has a height extending from a first side to a second side 205, and is illustrated without any horizontal insulators to hinder heat transmission through the block layer 218. In some embodiments, this height can represent a relatively high percentage of the overall thickness of the power delivery substrate 200, such as between approximately 50% and 95% of the thickness, or between about 50% and 99%, or between about 70% and 90% of the thickness.

In some embodiments, a power delivery substrate can include additional layers on a side of the block layer opposite the side onto which the metallization layers are formed. For example, an insulator can be disposed over the side opposite the side of the metallization layers (e.g., the via layer 220, the conductive trace layer 222, and the bonding pad layer 224). This insulator may or may not include contact pads for connection to a ground or a power source or for a chip. In some cases, the power delivery substrate with the additional insulator layer can be disposed between two semiconductor chips. For example, one semiconductor chip (e.g., the chip 700) can be directly bonded (e.g., hybrid bonded) to the outermost layer of the metallization layer portion of the power delivery substrate and a second semiconductor chip can be directly bonded (e.g., hybrid bonded) to the insulator layer, which can be treated to serve as a hybrid bonding layer.

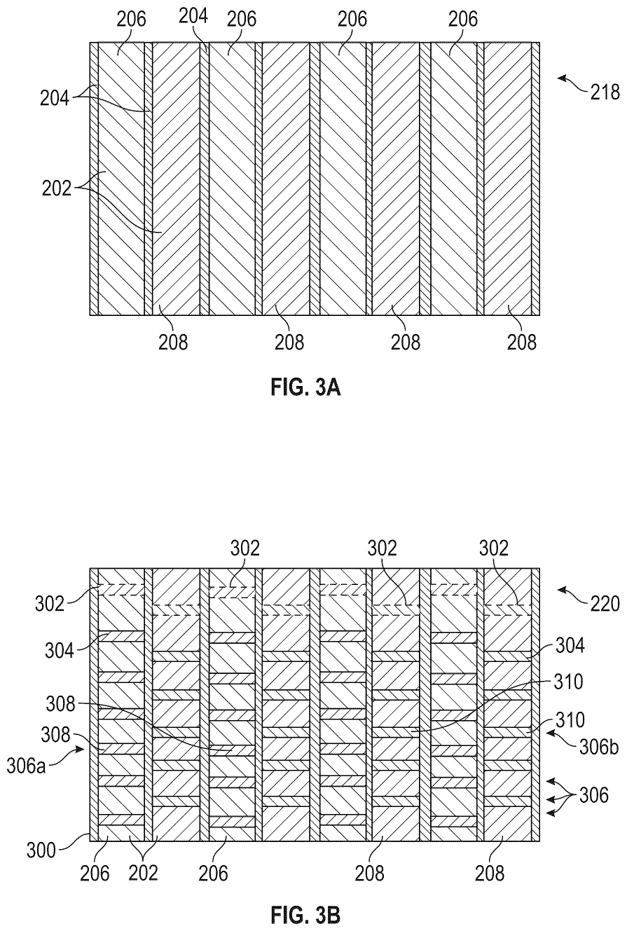

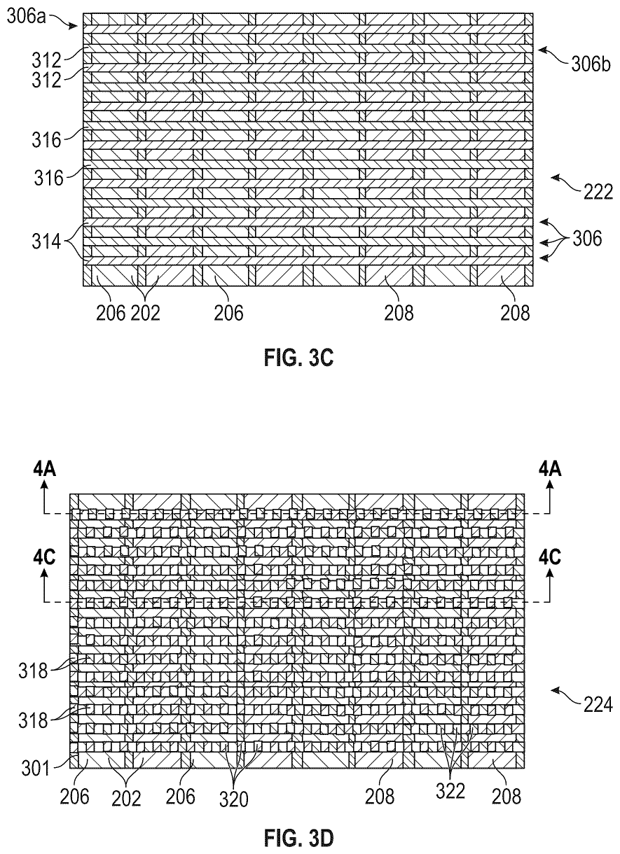

FIGS. 3A-3D schematically illustrate the different layers that may form a power delivery substrate 200, according to some embodiments. FIG. 3A shows the block layer 218, which as noted above can include a doped semiconductor substrate with a plurality of blocks 202, which in turn can be further characterized as ground blocks 206 or power blocks 208 depending on whether the ground blocks 206 or power blocks 208 are connected to ground or a power source. Insulating layers 204 are formed between the individual blocks 202 to electrically isolate the blocks from one another.

FIG. 3B shows an insulator layer 300 disposed over the block layer 218 and a plurality of vias or contacts 304 embedded in the insulator layer 300 such that the contacts 304 contact the blocks 202. In some embodiments, the insulator layer 300 can comprise an inorganic dielectric. In some embodiments, the insulator layer 300 can comprise a plurality of dielectrics. In some embodiments, the insulator layer 300 can comprise at least one of silicon oxide or silicon nitride, and it can have a thickness in a range between approximately 0.1 μm and 5 μm. The insulator layer 300 can have a CTE between approximately 0.5×10⁻⁶ K⁻¹ and 5×10⁻⁶ K⁻¹. The contacts 304 can be formed in any suitable fashion, such as by forming a plurality of openings 302 in the insulator layer 300 and filling the openings with a conductive material in a damascene process. The contacts 304 allow for electrical connection between the block layer 218 and other layers (e.g., the conductive trace layer 222, the bonding pad layer 224). In some cases, the contacts 304 can include a metal. In some cases, the contacts 304 comprise a metal selected from a group consisting of tungsten, nickel, copper, cobalt, aluminum, etc. In some cases, the material of the contacts 304 can also be selected to have a low CTE relative to copper (e.g., approximately less than 15×10⁻⁶ K⁻¹ or between approximately 5×10⁻⁶ K⁻¹ and 15×10⁻⁶ K⁻¹), such as tungsten or nickel.

The contacts 304 are formed in rows 306, which are cross with (e.g., are transverse or perpendicular to) direction of elongation of the blocks 202 formed in the block layer 218. The contacts 304 can include first contacts 308 and second contacts 310, such that the first contacts 308 are formed in a subset of the rows 306 and make direct contact with the ground blocks 206. Similarly, the second contacts 310 can be formed in a subset of the rows 306 and make direct contact with the power blocks 208. For example, and as shown in FIG. 3B, the first contacts 308can be formed in the rows 306a, which correspond to rows to be electrically connected to ground, over the ground blocks 206. The second contacts 310 can be formed in the rows 306b, which correspond to rows to be electrically connected to a power, over the power blocks 208. Thus, the rows of 306a, 306b of contacts 304 cross with the ground blocks 206 and the power blocks 208.

With reference to FIG. 3C, a plurality of conductive traces 312 (which can include the same materials as the contacts 304) can then be formed over and aligned with the rows 306 of contacts 304. For example, and as shown in FIG. 3C, the conductive trace layer 222 is formed, the traces 312 separated by insulating material. The conductive traces 312 can include ground conductive traces 314 to be electrically connected to ground and power conductive traces 316 to be electrically connected to power. FIG. 3C illustrates the ground conductive traces 314 as being formed over the rows 306a corresponding to the first contacts 308, which are in electrical connection with the ground blocks 206. The power conductive traces 316 are shown as being formed over the rows 306b corresponding to the second contacts 310, which are in electrical connection with the power blocks 208.

As shown in FIG. 3D, an insulator layer 301 can be disposed over the conductive trace layer 222 and a plurality of bonding pads 318 can be formed in the insulator layer 301, forming the bonding pad layer 224. In some examples, the insulator layer 301 is the outermost layer of the metallization layers in the power delivery substrate 200. Similar to insulator layer 300, in some embodiments, the insulator layer 301 can comprise an inorganic dielectric. In some embodiments, the insulator layer 301 can comprise a plurality of dielectrics. In some embodiments, the insulator layer 301 can comprise at least one of an oxide, a nitride, an oxynitride, and a carbonitride, and can be suitable for direct bonding. The insulator layer 301 can have a thickness in a range between approximately 0.1 μm and 5 μm, and it can have a CTE between approximately 0.5×10⁻⁶ K⁻¹ and 5×10⁻⁶ K⁻¹.

FIG. 3D illustrates bonding pads 318 can include ground bonding pads 320 to be electrically connected to ground and power bonding pads 322 to be electrically connected to power. The ground bonding pads 320 can be formed over the rows 306a including the ground conductive traces 314, and the power bonding pads 322 can be formed over the rows 306b including the power conductive traces 316. With this configuration for the power delivery substrate 200, the plurality of bonding pads 318 can be distributed with a first pitch in at least one dimension in a range of approximately 0.1 μm and 5 μm. In some embodiments, the ground blocks 206 and power blocks 208 can be arrayed with a second pitch, such that the first pitch is finer than the second pitch. This arrangement facilitates the electrical connection from the relatively large dimension ground blocks 206 and power blocks 208 through intervening layers 222 (FIGS. 3C) and 224 (FIG. 3D) to the backside of a chip having a fine array of bonding pads to provide power and ground to the chip.

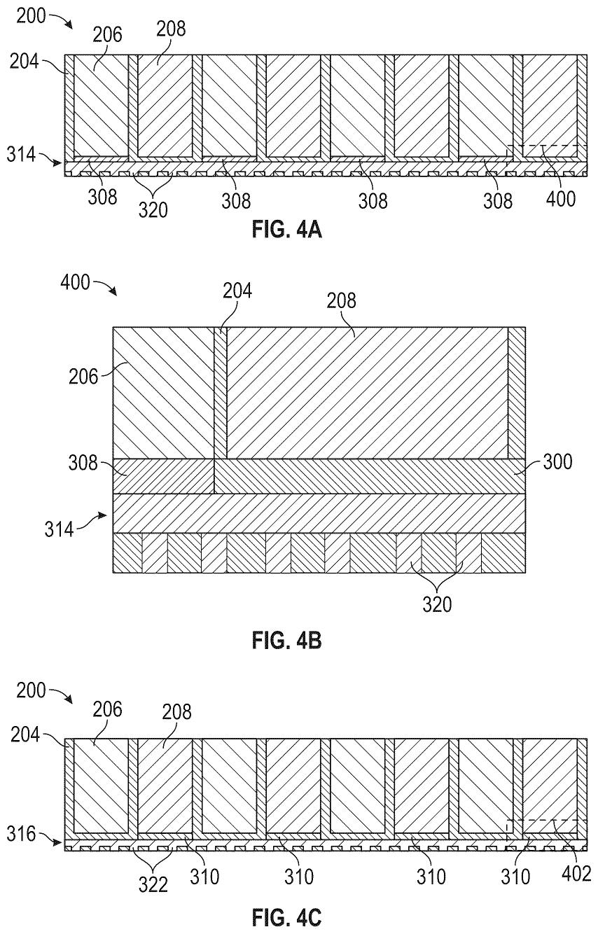

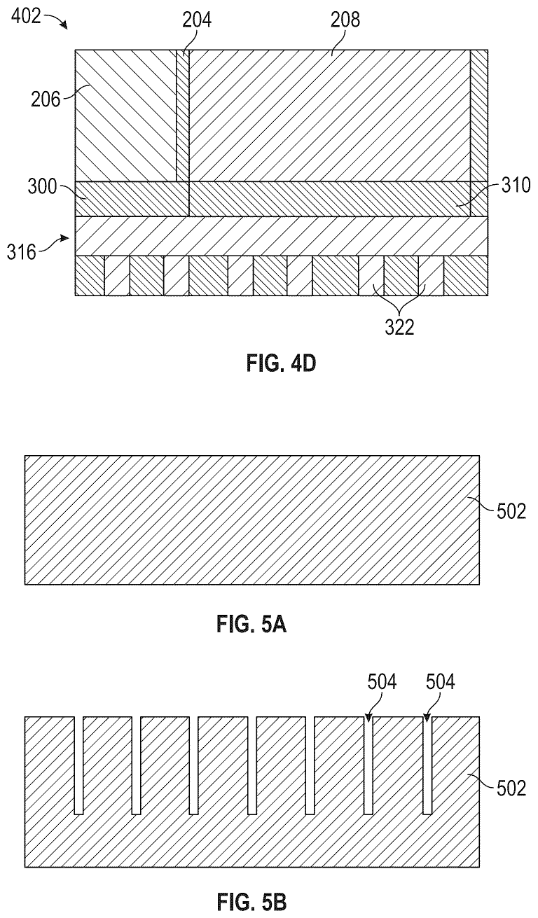

FIGS. 4A-4D further illustrate an arrangement of conductive traces and bonding pads relative to the blocks 202 in a side cross-sectional view of the power delivery substrate 200. In particular, FIG. 4A shows the side cross-sectional view of the power delivery substrate 200 along lines 4A-4A of FIG. 3D. FIG. 4C shows the side cross-sectional view of the power delivery substrate 200 along lines 4C-4C of FIG. 3D. FIG. 4B illustrates a magnified view of the dashed region 400 of FIG. 4A. FIG. 4B shows that the ground blocks 206 are electrically isolated from the power blocks 208 by the insulating layers 204, while the power blocks 208 are electrically insulated from the ground traces 314 by the insulator layer 300. The ground blocks 206 are electrically connected to the first contacts 308, the first contacts 308 are electrically connected to the ground conductive traces 314, and the ground conductive traces 314 are electrically connected to the ground bonding pads 320. FIG. 4D illustrates a magnified view of the dashed region 402 of FIG. 4C. FIG. 4C shows that the power blocks 208 are electrically isolated from the ground blocks 206 by insulating layers 204, while the ground blocks 206 are electrically insulated from the power conductive traces 316 by the insulator layer 300. The power blocks 208 are electrically connected to the second contacts 310, the second contacts 310 are electrically connected to the power conductive traces 316, and the power conductive traces 316 are electrically connected to the power bonding pads 322.

In some embodiments, a power delivery substrate 200 can be formed through a process where the blocks 202 are formed before the metallization steps occur. In some embodiments, the power delivery substrate 200 can be formed through a process where the blocks 202 are formed after the metallization steps occur.

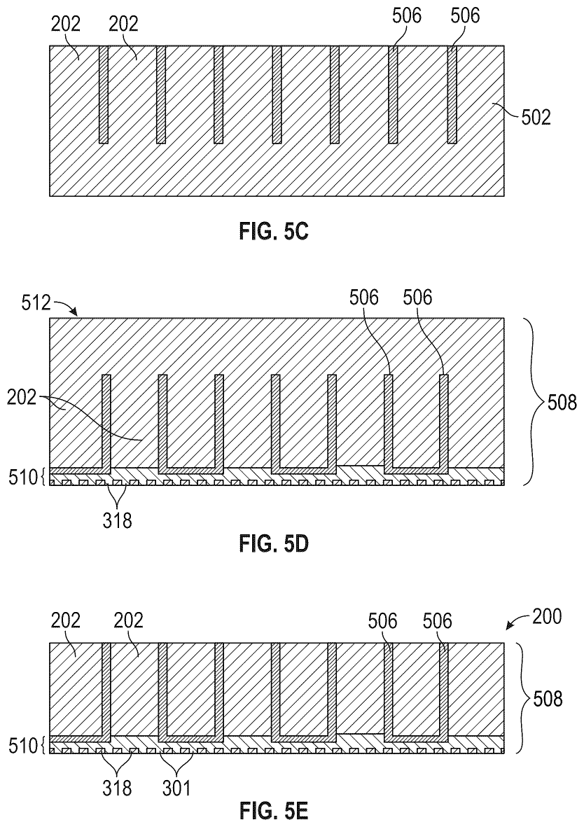

FIGS. 5A-5E illustrate a process of forming a power delivery substrate 200, where the metallization steps occur after formation of the blocks 202. A substrate 502 is first acquired (FIG. 5A). The substrate 502 can be a semiconductor material. In some examples, the substrate is a doped semiconductor material. In some examples, the doped semiconductor material is a doped silicon crystal or doped polycrystalline silicon, and the substrate can be a wafer, only a small section of which is shown. The blocks 202 are formed in the substrate 502. In FIG. 5B, a plurality of etched regions 504 is formed in the substrate 502. In some cases, the etching can be done through a dry etch for relatively vertical sidewalls, but in other embodiments a wet etch can be used. The etched regions 504 are then filled with one or more insulators 506, as shown in FIG. 5C. Filling the etched regions 504 with the insulator 506 provides electrical isolation between the blocks 202, allowing for at least one of the blocks 202 to be electrically connected to a ground and at least one of the blocks 202 to be electrically connected to a power. In FIG. 5D, the structure 508 that is formed after filling in the plurality of etched regions 504 can then have one or more metallization layers 510 formed on the side of the structure 508 that was etched. The metallization layers 510 can include, for example, the via layer 220, the trace layer 222 and the bonding pad layer 224 as shown in and described with respect to FIGS. 2A-4D. In some embodiments, the metallization layers can be formed using deposition processes. In some embodiments, the metallization layers can be formed using processes similar to damascene or dual damascene processes, such that more than one layer can be formed simultaneously. The side 512 of the structure 508 that is opposite the metallization layers 510 can be thinned (e.g., grinding, chemical mechanical polishing (CMP), etc.), typically after forming the metallization layer. In some embodiments, the side 512 is thinned until the ends of the insulator 506, which fill the plurality of etched regions 504, are exposed. The insulator layer 301 and bonding pads 318 are treated for hybrid bonding, such as the fine polishing, activation and/or termination as described with respect to FIGS. 1A and 1B, such that the bonding pad layer 224 serves as a hybrid bonding layer. The substrate 502 can be singulated to form multiple power delivery substrates 200.

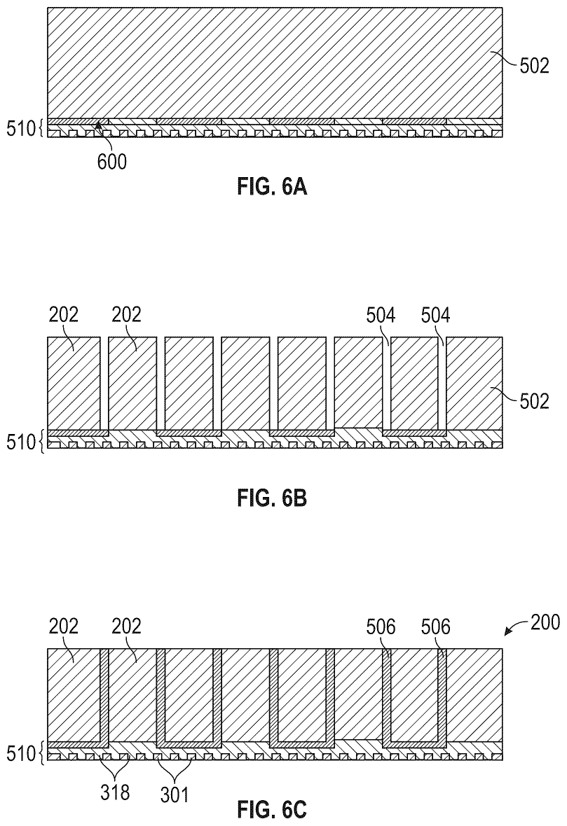

FIGS. 6A-6C illustrate a process of forming a power delivery substrate 200, where metallization occurs before formation of the blocks 202. A substrate 502 is provided (FIG. 6A). The substrate 502 can be a doped semiconductor material, as described herein. As shown in FIG. 6A, at least one metallization layer 510 can be formed on a side 600 of the substrate 502. The metallization layers 510 can include, for example, the via layer 220, the trace layer 222, and the bonding pad layer 224 as shown in and described with respect to FIGS. 2A-4D, and any suitable metallization processes can be employed, such as dual damascene processes to simultaneously form the contacts and traces. A plurality of etched regions 504 can then be formed in the substrate 502 on the side opposite the metallization layers 510 (FIG. 6B). In FIG. 6C, the etched regions 504 are filled with an insulator 506. As described with respect to FIGS. 5A-5E, the substrate can be thinned, prepared for hybrid bonding, and singulated, not necessarily in that order. For example, in some embodiments, the substrate 502 may be thinned before the etched regions 504 are formed.

As noted, once the power delivery substrate 200 is formed, the bonding pad layer 224 can be further processed or prepared for a direct bonding (e.g., hybrid bonding) step, as illustrated in FIG. 7A. Direct bonding (and hybrid bonding) is disclosed herein. The additional processing steps may include polishing steps, activation and/or termination steps (e.g., plasma activation can provide both activation and termination), etc. and yield a bonding layer to which a chip 700 can be hybrid bonded. The insulator layer of the power delivery substrate 200 can include a first dielectric 701 and a plurality of first bonding pads 703. The chip 700 has a frontside 702, a backside 704, and can have a plurality of interconnects 710 (e.g., TSVs). The backside 704 of the chip 700 can include a bonding layer 706 that in turn comprises a second dielectric 708 and revealed interconnects 710 and/or second bonding pads 712, and the plurality of first bonding pads 703 can directly bond to the revealed interconnects 710 and/or second bonding pads 712 along the bonding interface 714. In some embodiments, and as shown in FIG. 7A, the power delivery substrate 200 can have its side 512 (e.g., FIG. 5D) thinned (e.g., lapped, etc.) prior to bonding to the chip 700. In some embodiments, the thinning can occur post-bonding. Post-bonding thinning can be beneficial where the chip to be bonded is very thin (e.g., less than 50 μm thick), as the power delivery substrate 200 can act as a carrier during processing (e.g., it can provide a thick element for processing, and then be thinned to dotted line 715 post-processing/post-bonding).

As shown in FIG. 7B, in some embodiments, a liquid cooling structure 716 can be directly bonded to the back of the power delivery substrate 200 after it is thinned (e.g., thinned to dotted line 715 as shown in FIG. 7A). The liquid cooling structure can facilitate heat dissipation of the structure, further enhancing the operation of the semiconductor device. The liquid cooling structure 716 can have one or more cavities 718 or channels, an inlet 720, and an outlet 722. In some embodiments, a cooled liquid can propagate through the inlet 720 into the one or more cavities 718. Heat generated from the chip 700 can move through the power delivery substrate 200 and contact the liquid cooling structure 716. The heat is transferred to the liquid, resulting in a heated liquid that can be transferred out of the cooling structure 716 through the outlet 722. In some embodiments, the liquid cooling structure 716 can be directly bonded to the power delivery substrate 200 (e.g., at a bonding interface 724) prior to the power delivery substrate 200 being directly bonded to the chip 700. In some embodiments, instead of the liquid cooling structure 716, a heat pipe, a vapor chamber, a thermoelectric cooling element, or any other suitable cooling structure known in the art may be direct bonded to the power delivery substrate 200 and facilitate heat dissipation. In some embodiments, one or more of the cavities 718 can be open to the power delivery substrate 200, such that the cooling liquid directly contacts the power delivery substrate 200.

Beneficially, the configuration of the power delivery substrate 200 does not prevent heat from dissipating through the power delivery substrate 200. The doped semiconductor layer of the power delivery substrate 200 can have a relatively high thermal conductivity to facilitate heat dissipation from heat generated in a chip 700 to which the power delivery substrate 200 is bonded. Use of a single layer of semiconductor blocks can also improve thermal conductivity of the power delivery substrate 200, without insulating layers within the semiconductor blocks to hinder thermal flow. Further, a cooling structure (e.g., 201 or 716) can be directly bonded to the power delivery substrate 200 to further enable efficient thermal dissipation in an assembly including at least the power delivery substrate 200 and the chip 700. Additionally, for embodiments providing direct contact between cooling fluid and the power delivery substrate 200, direct bonding also facilitates sealing the cavities 718 against the power delivery substrate 200. Thus, the power delivery substrate 200 can simultaneously distribute power and ground to the backside of a chip 700 and provide an efficient thermal pathway for the heat generated by the chip 700.

Additionally, the power delivery substrate 200 disclosed includes a relatively thick electrically conductive doped semiconductor layer as compared to its metallization layers. The doped semiconductor layer is a thick, low CTE layer, which can help to address potential CTE mismatch issues that can arise between the power delivery substrate 200 and a chip 700. For example, after thinning of the power delivery substrate 200 occurs, the relative thickness of the structure 508 (or block layer 218) relative to the metallization layers 510 can be controlled so that the effective CTE of the power delivery substrate 200 can be made closer to the CTE of the chip 700. Specifically, if the structure 508 comprises a material having a CTE similar to that of the chip 700 and if the structure 508 dominates the thickness of the power delivery substrate 200 (e.g., if the structure 508 is between 50% and 99%, 60% and 98%, 50% and 95%, or 70% and 90% of the thickness of the power delivery substrate 200), then a better CTE match between the power delivery substrate 200 and the chip 700 can be achieved, which can help prevent structural integrity issues that may arise during operation of a semiconductor device having layers with mismatched CTE values.

Generally, an element intended for backside power delivery may be substantially thicker than the chip to which the element is to be attached. The bigger the difference in thicknesses, the more significant the potential CTE-mismatch problem. Thus, with the post-thinned power delivery substrate 200 having a structure 508 with block layer 218 having a relative thickness greater than that of the metallization layers 510, better CTE matching can occur with respect to the chip to be attached, and thus the potential CTE-mismatch problem between these differently sized layers (the power delivery substrate 200 and the chip 700) is mitigated.

In one aspect, the techniques described herein relate to a power delivery substrate, including: a doped semiconductor including a plurality of ground blocks, a plurality of power blocks parallel to the ground blocks, and an insulator disposed between the ground blocks and the power blocks. The ground blocks and the power blocks are coplanar, and a plurality of conductive traces is disposed over and in electrical contact with the ground blocks and the power blocks. An insulator layer is included, such that the conductive traces are between the doped semiconductor and the insulator layer. A plurality of bonding pads is embedded in the insulator layer, and the bonding pads are electrically connected to the conductive traces.

In some embodiments, the power delivery substrate further includes a second insulator layer between the conductive traces and the doped semiconductor. The second insulator layer can include a plurality of contacts therethrough, and the contacts connect the ground and power blocks with the conductive traces. In some embodiments, the second insulator layer has a thickness between approximately 0.1 μm and approximately 5 μm. In some embodiments, one or both of the insulator layer and the second insulator layer include a nitride.

In some embodiments, the bonding pads include a plurality of first bonding pads to electrically connect to a first ground source and a plurality of second bonding pads to electrically connect to a first power source.

In some embodiments, the doped semiconductor includes a doped silicon crystal. In some embodiments, the doped silicon crystal includes a doping concentration between approximately 10¹⁸ atoms/cm³ and approximately 10²² atoms/cm³. In some embodiments, the doped silicon crystal is doped with at least one of arsenic, boron, phosphorous, or gallium.

In some embodiments, the doped semiconductor includes a doped polycrystalline silicon.

In some embodiments, at least the insulator layer has a coefficient of thermal expansion between approximately 0.5×10⁻⁶ K⁻¹ and approximately 5×10⁻⁶ K⁻¹.

In some embodiments, the bonding pads are distributed with a first pitch in a range of approximately 0.1 μm and approximately 5 μm. In some embodiments, the ground blocks and the power blocks are arrayed with a second pitch, where the first pitch is finer than the second pitch.

In some embodiments, the doped semiconductor has a thermal conductivity in a range of approximately 50 Wm⁻¹ K⁻¹ and approximately 200 Wm⁻¹ K⁻¹. In some embodiments, the power delivery substrate includes a first thickness, and the doped semiconductor includes a second thickness that is between approximately 70% and 90% of the first thickness.

In some embodiments, the power delivery substrate further includes a plurality of second power blocks, where the second power blocks are electrically isolated from the power blocks and the ground blocks.

In some embodiments, the ground and power blocks represent the only semiconductor layer in the substrate.

In some embodiments, an individual block of the ground and power blocks has a width in a range of approximately 1 mm and approximately 5 mm.

In some embodiments, the power delivery substrate further includes a first connector rail to connect the ground blocks to one another and a second connector rail connect the power blocks to one another. In some embodiments, the first connector rail is disposed on a side of the doped semiconductor, and the second connector rail is disposed on an opposing side of the doped semiconductor.

In some embodiments, the power delivery substrate has a thickness between approximately 10 μm and approximately 500 μm.

In some embodiments, the power delivery substrate is a backside power delivery element hybrid bonded to a backside of a semiconductor chip including a frontside and the backside. An active region of the semiconductor chip is located nearer to the frontside than the backside.

In another aspect, the techniques described herein relate to a microelectronic bonded structure, including a power and ground distribution structure including a doped semiconductor having a plurality of first regions and a plurality of second regions in one layer. The first regions are electrically isolated from the second regions. The power and ground distribution structure also includes a plurality of first conductive traces disposed over the doped semiconductor and coupled to the first regions; a plurality of second conductive traces disposed over the doped semiconductor and coupled to the second regions; and a plurality of first bonding pads disposed over and coupled to the first and second conductive traces. The bonded structure also includes a chip including a frontside, a backside, and an active region disposed nearer the frontside than the backside. The power and ground distribution structure is hybrid bonded to the backside of the chip.

In some embodiments, the power and ground distribution structure includes a first dielectric and the first bonding pads, and the backside of the chip includes a second dielectric and a plurality of second bonding pads. The first and the second dielectrics are directly bonded to each other and the first and second bonding pads are directly bonded to each other. In some embodiments, the first dielectric has a coefficient of thermal expansion between approximately 0.5×10⁻⁶ K⁻¹ and approximately 5×10⁻⁶ K⁻¹.

In some embodiments, the first regions are coupled to at least a first ground source and the second regions are coupled to at least a first power source. An insulator separates the first regions from the second regions. In some embodiments, the microelectronic bonded structure further includes a plurality of third regions, where the plurality of third regions is coupled to at least a second power source and the third regions are electrically isolated from the first and second regions. In some embodiments, the insulator includes at least one of a nitride or an oxide.

In some embodiments, the microelectronic bonded structure further includes a cooling element disposed over the power and ground distribution structure.

In some embodiments, the doped semiconductor is a doped silicon crystal. In some embodiments, the doped silicon crystal includes a doping concentration between approximately 1018 atoms/cm³ and approximately 1022 atoms/cm³. In some embodiments, the doped silicon crystal is doped with at least one of arsenic, boron, phosphorous, or gallium.

In some embodiments, the plurality of first bonding pads includes a pitch in a range of approximately 0.1 μm and approximately 5 μm.

In some embodiments, the doped semiconductor has a thermal conductivity in a range of approximately 50 Wm⁻¹ K⁻¹ and approximately 200 Wm⁻¹ K⁻¹.

In some embodiments, the power and ground distribution structure has a thickness between approximately 10 μm and approximately 500 μm.

In some embodiments, the power and ground distribution structure has a single layer of the doped semiconductor.

In some embodiments, the first and second regions include parallel blocks, and the first regions have widths in a range of approximately 10 μm and approximately 100 μm. In some embodiments, the microelectronic bonded structure further includes a first semiconductor connector rail on a side of the doped semiconductor to connect the first regions to one another and providing a second semiconductor connector rail on an opposing side of the doped semiconductor to connect the second regions to one another. The first and second semiconductor connector rails are perpendicular to the first regions and the second regions.

In some embodiments, one or more of the first conductive traces, second conductive traces, and first bonding pads include a metal selected from a group consisting of tungsten, nickel, and cobalt.

In another aspect, the techniques described herein relate to a method of forming a microelectronic device. The method includes forming a plurality of ground blocks in a doped semiconductor substrate and a plurality of power blocks in the doped semiconductor substrate. The ground blocks and the power blocks are coplanar, and insulators electrically isolate the ground blocks from the power blocks. The method also includes forming a plurality of first conductive traces crossing and in electrical contact with the ground blocks; forming a plurality of second conductive traces crossing and in electrical contact with the power blocks; depositing an insulator layer over the first conductive traces and the second conductive traces; forming a plurality of bonding pads in the insulator layer, where the bonding pads are electrically connected to the ground blocks and the power blocks; and directly bonding the insulator layer and the bonding pads to a backside of a chip. The chip includes a frontside and the backside, where an active region of the chip is nearer to the frontside.

In some embodiments, the doped semiconductor substrate includes a doped silicon crystal.

In some embodiments, the insulator layer has a coefficient of thermal expansion between approximately 0.5×10⁻⁶ K⁻¹ and approximately 5×10⁻⁶ K⁻¹.

In some embodiments, the bonding pads have a pitch in a range of approximately 0.1 μm and approximately 5 μm.

In some embodiments, the method further includes forming the first conductive traces and the second conductive traces in a dielectric layer disposed over the doped semiconductor substrate.

In some embodiments, the forming of the ground and power blocks includes providing a single layer of the doped semiconductor substrate, and the ground and power blocks extend across the doped semiconductor substrate.

In some embodiments, the method further includes providing a first semiconductor connector rail on a lateral side of the doped semiconductor to connect the ground blocks to one another and providing a second semiconductor connector rail on an opposing lateral side of the doped semiconductor to connect the plurality of second blocks to one another. The first and second semiconductor connector rails are perpendicular to the ground and power blocks. In some embodiments, the method further includes providing contacts in an other insulator layer, and the contacts and the other insulator layer are positioned between the first and second conductive traces and the ground and power blocks.

In another aspect, the techniques described herein relate to a method of forming a power delivery substrate. The method includes forming one or more metallization layers over a first side of a doped semiconductor substrate. The one or more metallization layers includes a plurality of bonding pads in an outermost layer of the one or more metallization layers. The method also includes forming a plurality of blocks in the doped semiconductor substrate. The blocks include at least a first block to couple to ground and a second block to couple to a power source. The first block and the second block are coplanar, and the doped semiconductor is a sole semiconductor layer in the power delivery substrate. The blocks are electrically coupled to the bonding pads.

In some embodiments, the forming of the one or more metallization layers is conducted before forming the blocks in the doped semiconductor substrate.

In some embodiments, the power delivery substrate is devoid of active devices.

In some embodiments, the blocks extend along a length of the doped semiconductor substrate.

In some embodiments, the doped semiconductor substrate includes an insulating separator, and the insulating separator electrically isolates the first block from the second block.

In some embodiments, the doped semiconductor substrate includes a doped silicon crystal.

In some embodiments, the outermost layer of the one or more metallization layers includes at least one of a nitride or an oxide.

In some embodiments, the outermost layer of the one or more metallization layers has a coefficient of thermal expansion between approximately 5×10⁻⁶ K⁻¹ and approximately 15×10⁻⁶ K⁻¹.

In some embodiments, the bonding pads are arrayed with a pitch in a range of approximately 0.1 μm and approximately 5 μm.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only and are not intended to limit the scope of the disclosure. Indeed, the novel apparatus, methods, and systems described herein may be embodied in a variety of other forms; furthermore, various omissions, substitutions, and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A power delivery substrate, comprising:
a doped semiconductor comprising a plurality of ground blocks, a plurality of power blocks parallel to the ground blocks, and an insulator disposed between the ground blocks and the power blocks, wherein the ground blocks and the power blocks are coplanar;
a plurality of conductive traces disposed over and in electrical contact with the ground blocks and the power blocks;
an insulator layer, wherein conductive traces are between the doped semiconductor and the insulator layer; and
a plurality of bonding pads embedded in the insulator layer, the bonding pads being electrically connected to the conductive traces.

2. The power delivery substrate of claim 1, further comprising a second insulator layer between the conductive traces and the doped semiconductor, the second insulator layer comprising a plurality of contacts therethrough, the contacts connecting the ground and power blocks with the conductive traces, wherein the second insulator layer has a thickness between approximately 0.1 μm and approximately 5 μm.

3. (canceled)

4. (canceled)

5. The power delivery substrate of claim 1, wherein the bonding pads comprise a plurality of first bonding pads to electrically connect to a first ground source and a plurality of second bonding pads to electrically connect to a first power source.

6. The power delivery substrate of claim 1, wherein the doped semiconductor comprises a doped silicon crystal, wherein the doped silicon crystal comprises a doping concentration between approximately 10¹⁸ atoms/cm³ and approximately 10²² atoms/cm^{3.}

7. (canceled)

8. (canceled)

9. (canceled)

10. (canceled)

11. The power delivery substrate of claim 1, wherein the bonding pads are distributed with a first pitch in a range of approximately 0.1 μm and approximately 5 μm, and wherein the ground blocks and the power blocks are arrayed with a second pitch, wherein the first pitch is finer than the second pitch.

12. (canceled)

13. The power delivery substrate of claim 1, wherein the doped semiconductor has a thermal conductivity in a range of approximately 50 Wm⁻¹K⁻¹ and approximately 200 Wm⁻¹K⁻¹.

14. (canceled)

15. The power delivery substrate of claim 1, further comprising a plurality of second power blocks, wherein the second power blocks are electrically isolated from the power blocks and the ground blocks.

16. The power delivery substrate of claim 1, wherein the ground and power blocks represent the only semiconductor layer in the substrate.

17. (canceled)

18. The power delivery substrate of claim 1, further comprising a first connector rail to connect the ground blocks to one another and a second connector rail to connect the power blocks to one another.

19. (canceled)

20. (canceled)

21. A semiconductor package including the power delivery substrate of Claim 1, wherein the power delivery substrate is a backside power delivery element hybrid bonded to a backside of a semiconductor chip comprising a frontside and the backside, wherein an active region of the semiconductor chip is located nearer to the frontside than the backside.

22. A microelectronic bonded structure, comprising:
a power and ground distribution structure comprising:
a doped semiconductor having a plurality of first regions and a plurality of second regions in one layer, the first regions being electrically isolated from the second regions;
a plurality of first conductive traces disposed over the doped semiconductor and coupled to the first regions;
a plurality of second conductive traces disposed over the doped semiconductor and coupled to the second regions;
a plurality of first bonding pads disposed over and coupled to the first and second conductive traces; and
a chip comprising a frontside, a backside, and an active region disposed nearer the frontside than the backside, wherein the power and ground distribution structure is hybrid bonded to the backside of the chip.

23. The microelectronic bonded structure of claim 22, wherein the power and ground distribution structure comprises a first dielectric and the first bonding pads, wherein the backside of the chip comprises a second dielectric and a plurality of second bonding pads, wherein the first and the second dielectrics are directly bonded to each other and the first and second bonding pads are directly bonded to each other.

24. (canceled)

25. The microelectronic bonded structure of claim 22, wherein the first regions are coupled to at least a first ground source and the second regions are coupled to at least a first power source, wherein an insulator separates the first regions from the second regions, and wherein the insulator comprises at least one of a nitride or an oxide.

26. (canceled)

27. (canceled)

28. The microelectronic bonded structure of claim 22, further comprising a cooling element disposed over the power and ground distribution structure.

29. (canceled)

30. (canceled)

31. (canceled)

32. (canceled)

33. (canceled)

34. (canceled)

35. The microelectronic bonded structure of claim 22, wherein the power and ground distribution structure has a single layer of the doped semiconductor.

36. (canceled)

37. (canceled)

38. (canceled)

39. A method of forming a microelectronic device, the method comprising:
forming a plurality of ground blocks in a doped semiconductor substrate and a plurality of power blocks in the doped semiconductor substrate, wherein the ground blocks and the power blocks are coplanar, and wherein insulators electrically isolate the ground blocks from the power blocks;
forming a plurality of first conductive traces crossing and in electrical contact with the ground blocks;
forming a plurality of second conductive traces crossing and in electrical contact with the power blocks;
depositing an insulator layer over the first conductive traces and the second conductive traces;
forming a plurality of bonding pads in the insulator layer, wherein the bonding pads are electrically connected to the ground blocks and the power blocks; and
directly bonding the insulator layer and the bonding pads to a backside of a chip, the chip comprising a frontside and the backside, wherein an active region of the chip is nearer to the frontside.

40. (canceled)

41. (canceled)

42. The method of claim 39, wherein the bonding pads have a pitch in a range of approximately 0.1 μm and approximately 5 μm.

43. The method of claim 39, further comprising forming the first conductive traces and the second conductive traces in a dielectric layer disposed over the doped semiconductor substrate.

44. The method of claim 39, wherein forming the ground and power blocks comprises providing a single layer of the doped semiconductor substrate, and wherein the ground and power blocks extend across the doped semiconductor substrate.

45. The method of claim 39, further comprising providing a first semiconductor connector rail on a lateral side of the doped semiconductor to connect the ground blocks to one another and providing a second semiconductor connector rail on an opposing lateral side of the doped semiconductor to connect the plurality of second blocks to one another, wherein the first and second semiconductor connector rails are perpendicular to the ground and power blocks.

46. (canceled)

47. (canceled)

48. (canceled)

49. (canceled)

50. (canceled)

51. (canceled)

52. (canceled)

53. (canceled)

54. (canceled)

55. (canceled)
